(19) United States
(12) Patent Application Publication
(10) Pub. No.: US 2011/0226059 A1
(43) Pub. Date: Sep. 22, 2011

(54) SENSOR AND METHOD FOR MANUFACTURING A SENSOR

(76) Inventors: Patrick Wellner, Stuttgart (DE); Christian Patak, Reutlingen (DE); Lars Tebje, Reutlingen (DE); Helmut Grutzeck, Kusterdingen (DE); Volker Materna, Munchen (DE)

(21) Appl. No.: 12/737,944

(22) PCT Filed: Aug. 4, 2009
(86) PCT No.: PCT/EP2009/060073

§ 371 Date: Jun. 13, 2011

(30) Foreign Application Priority Data
Sep. 25, 2008 (DE) 10 2008 042 366.1

(51) Int. Cl. G01P 15/02; H05K 3/00

(52) U.S. Cl. 73/514.01; 29/829

(57) ABSTRACT

A sensor having a substrate, a cap and a seismic mass is proposed, the substrate having a main extension plane, the seismic mass being deflectable perpendicular to the main extension plane, a first stop of the cap covering a first area of the seismic mass perpendicular to the main extension plane in a first coverage region and a second stop of the cap covering a second area of the seismic mass perpendicular to the main extension plane in a second coverage region, and furthermore the first and second coverage regions parallel to the main extension plane being essentially equal in size. The distances of the coverage regions from a pivot axis of the mass designed as a rocker are equal so that the torques caused by electronic forces offset one another.

### BACKGROUND OF THE INVENTION

1. Field of the Invention

The present information is generally directed to a sensor.

2. Description of Related Art

Such sensors are generally known. For example, a micromechanical acceleration sensor having an inertia weight in the form of a rocker which is deflectable in the z direction is known from publication published German patent document DE 10 2006 026 880 A1, a stop device being provided on the side of the shorter lever arm for shortening the possible deflection if the lever arms of the rocker are of varying lengths in order to prevent asymmetrical clipping. A disadvantage of this system for shortening the possible deflection of the inertia weight in the z direction is that a one-sided electrostatic interaction between the inertia weight and the stop device influences the behavior of the inertia weight. Furthermore, publication published German patent document DE 198 00 574 A1 describes an acceleration sensor having a capping wafer for covering a micromechanical structure of the acceleration sensor.

### SUMMARY OF THE INVENTION

In contrast to the related art, the sensor according to the present invention and the method according to the present invention for manufacturing a sensor according to the other independent claims have the advantage that on the one hand, the deflection of the seismic mass is limited by the first and second stops and on the other hand, the behavior of the seismic mass is not influenced or is only immaterially influenced by the first and second stops. Furthermore, the sensor according to the present invention may be manufactured comparatively simply and cost-effectively, since the design of the first and second stops as part of the cap for positioning the first and second stops only makes it necessary to place the cap on the substrate. Furthermore, the manufacturing tolerances when positioning the cap on the substrate parallel to the main extension plane in particular are substantially increased in the sensor according to the present invention. This is achieved in that the first and second coverage regions are essentially of equal size, so that in particular in the case of an electrically conductive contact between the first and second stops across the rest of the cap, a first electrostatic interaction between the first area and the first stop is equal to a second electrostatic interaction between the second area and a second stop. Thus, the first and second electrostatic interactions on the seismic mass are offset and no or only an insignificant resulting torque acts on the seismic mass having an axis of rotation parallel to the main extension plane. The first and second stops are placed on the substrate using the cap in particular in such a way that when the cap is displaced in relation to the substrate parallel to the main extension plane, the size of the first coverage region changes to be equal to the size of the second transition area and accordingly the cap need not be positioned as precisely on the substrate, but nonetheless compensation is achieved between the first and second electrostatic interactions. In particular a measurement of an acceleration perpendicular to the main extension plane, i.e., in the z direction, is not or is only insignificantly influenced by the first and second stops. Furthermore, for example, a measurement of an acceleration parallel to the main extension plane, i.e., in the x and/or y direction, is also not influenced or is only insignificantly influenced by the first and second stops, since the first and second electrostatic interactions have at most a uniform force effect on the seismic mass in the z direction, and accordingly a tipping of the seismic mass about the axis of rotation parallel to the main extension plane is prevented, such a tipping entailing the risk of displacement of the center of mass of the seismic mass in the x and/or y direction and accordingly a falsification of the measurement.

According to another preferred refinement, it is provided that the seismic mass is situated perpendicular to the main extension plane essentially between the substrate and the cap, so that the seismic mass is advantageously protected on the one side by the substrate and on the other side by the cap. Preferably, electrodes are situated on the substrate between the seismic mass and the substrate and corresponding counter-electrodes are situated on the seismic mass, so that a deflection of the seismic mass in relation to the substrate and perpendicular to the main extension plane causes a change in the electric capacitance between electrodes and counter-electrodes and is thus quantifiable.

According to another preferred refinement, it is provided that the seismic mass is designed as a rocker structure, a pivot axis of the rocker structure being situated parallel to the main extension plane essentially between the first and second areas. It is particularly preferred that the seismic mass has an asymmetric mass distribution in relation to the pivot axis, so that an acceleration force acting perpendicularly to the main extension plane exerts a torque on the seismic mass about the pivot axis, a first deflection preferably including a rotation in a first direction of rotation about the pivot axis and a second deflection including a rotation in a second direction of rotation about the pivot axis opposite to the first direction of rotation. The first stop advantageously limits a maximal first deflection while the second stop limits a maximal second deflection.

According to another preferred refinement, it is provided that the seismic mass includes a first seismic partial mass and a second seismic partial mass, the first seismic partial mass having the first area and the second seismic partial mass having the second area, the first and the second seismic partial mass preferably being joined to one another by webs. It is particularly advantageous that a rocker structure having an asymmetric mass distribution in relation to the pivot axis may thus be implemented in a comparatively simple and space-saving manner, the first seismic partial mass having a mass which is unequal to the second seismic partial mass or the center of mass of the first seismic partial mass having a distance from the pivot axis which is unequal to the distance of the center of mass of the second seismic partial mass from the pivot axis.

According to another preferred refinement, it is provided that the first area includes a first edge area of the first seismic partial mass and the second area includes a second edge area of the second seismic partial mass, making it possible to implement the sensor according to the present invention in a comparatively compact installation space, and a change in size of the first coverage region by a displacement of the first stop parallel to the main extension plane in relation to the first edge area causes an equal change in size of the second coverage region, since the second stop is also inevitably displaced in relation to the second edge area parallel to the main extension plane in preferably the same manner as the displacement of the first stop across the cap.

According to another preferred refinement, it is provided that the first and second stops are situated in relation to the seismic mass in such a way that a first electrostatic interaction between the first stop and the first area is essentially identical to a second electrostatic interaction between the second stop and the second area, so that the first and second electrostatic interactions advantageously offset one another and thus the behavior of the seismic mass is not or is only insignificantly influenced, in particular in an acceleration effect perpendicular to the main extension plane.

According to another preferred refinement, it is provided that the sensor includes a micromechanical sensor and in particular a micromechanical acceleration sensor which is preferably provided to be sensitive to acceleration forces perpendicular to the main extension plane.

A further object of the present invention is a method for manufacturing a sensor, the cap together with the first and second stops being positioned on the substrate in one assembly step in such a way that the first and second coverage regions are essentially of equal size, so that, as already explained above, the first and second electrostatic interactions offset one another and thus do not influence or only insignificantly influence the behavior of the seismic mass. It is furthermore particularly advantageous that the first and second stops are positioned simultaneously in a single assembly step, thus ensuring the equality of the first and second coverage regions. The fixed connection between the first and second stops furthermore increases the manufacturing tolerances, since a change in size of the first coverage region automatically results in an identical change in size of the second coverage region. Accordingly, the cap must in particular be positioned on the substrate with significantly less precision.

Exemplary embodiments of the present invention are represented in the drawings and are elucidated in greater detail in the following description.

### BRIEF DESCRIPTION OF THE DRAWINGS

FIG. 1 shows a schematic perspective view of a substrate and a seismic mass of a sensor according to a first specific embodiment of the present invention.

FIG. 2 shows a schematic perspective view of a cap of a sensor according to the first specific embodiment of the present invention.

FIG. 3 shows a schematic perspective view of a sensor according to the first specific embodiment of the present invention.

FIG. 4 shows a schematic perspective view of a sensor according to a second specific embodiment of the present invention.

FIG. 5 shows a schematic perspective view of a sensor according to a third specific embodiment of the present invention.

FIG. 6 shows a schematic perspective view of a sensor according to a fourth specific embodiment of the present invention.

### DETAILED DESCRIPTION OF THE INVENTION

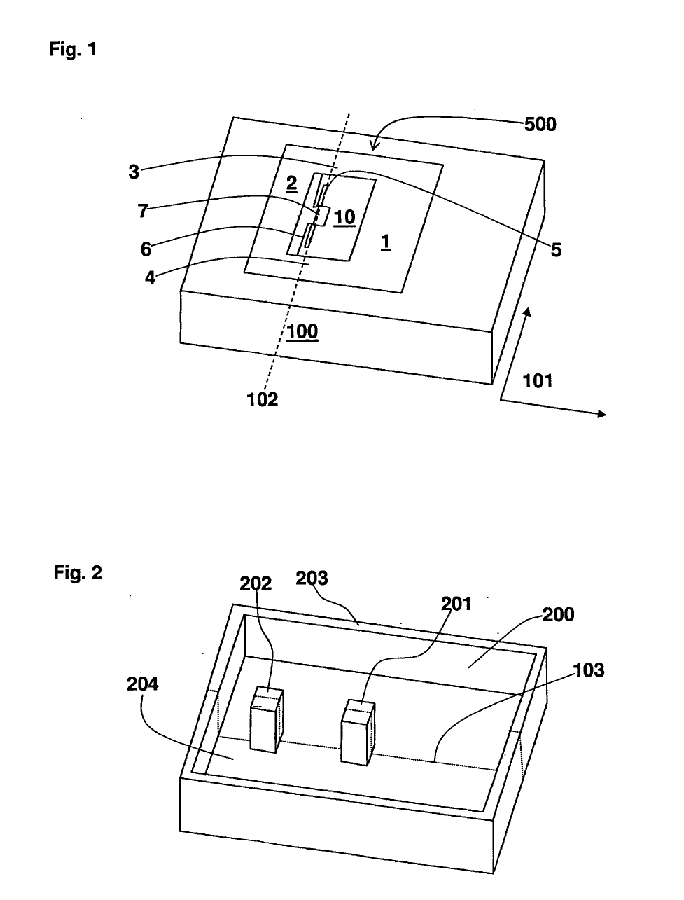

A schematic perspective view of a substrate 100 and a seismic mass 500 of a sensor according to a first specific embodiment of the present invention is represented in FIG. 1, substrate 100 having a main extension plane 101 and completely enclosing seismic mass 500 in a plane parallel to main extension plane 101. Seismic mass 500 includes a first seismic partial mass 1 and a second seismic partial mass 2, first and second seismic partial masses 1, 2 being joined to one another by a first and a second web 3, 4. An open space 10 is provided between first and second seismic partial masses 1, 2 and between first and second webs 3, 4. Alternatively, open space 10 includes an area which is connected to the electrical potential of substrate 100. Situated in open space 10 is an anchoring element 7 which is connected to substrate 100. Seismic mass 500 is attached to anchoring element 7 using suspension springs 5, making a movement of seismic mass 500 relative to substrate 100 possible. Suspension springs 5 preferably engage first and second webs 3, 4 and thus define in particular a pivot axis 102 parallel to main extension plane 101. First and second seismic partial masses 1, 2 include a varying mass and the center of gravity of the first seismic partial mass is at a distance from pivot axis 102 which is unequal to a distance from the center of gravity of the second seismic partial mass with respect to pivot axis 102, so that seismic mass 500 is designed as a rocker structure which is deflectable about pivot axis 102 and has an asymmetrical mass distribution in relation to pivot axis 102. An acceleration force acting on the sensor perpendicular to main extension plane 101, i.e., in the z direction, thus produces a deflection of seismic mass 500 about pivot axis 102.

A schematic perspective view of a cap 200 of a sensor according to the first specific embodiment of the present invention is represented in FIG. 2, cap 200 having a hollow space 204 in which a first and a second stop 201, 202 are situated and cap 200 having a frame 203 enclosing hollow space 204 parallel to main extension plane 101. First and second stops 201, 202 are connected to one another across the rest of the cap in an electrically conductive manner and are therefore essentially connected to the same electrical potential.

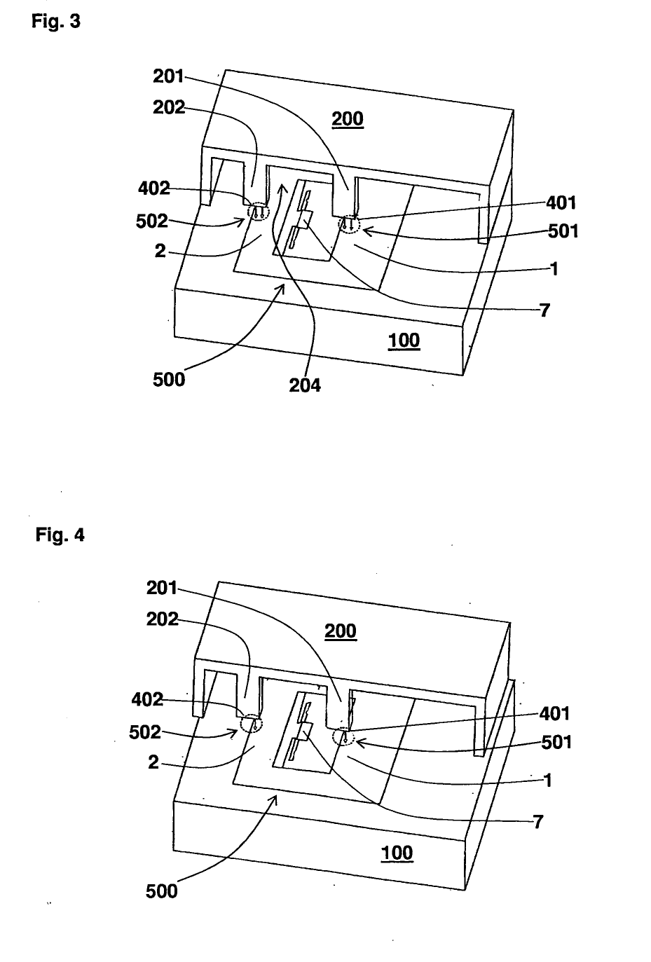

A schematic perspective view of a sensor according to the first specific embodiment of the present invention is represented in FIG. 3, FIG. 3 being essentially identical to FIG. 1 and additionally representing cap 200 from FIG. 2. However, in contrast to FIG. 2, a cross section of cap 200 is shown for the sake of clarity, the cross section corresponding to a section through cap 200 along line of intersection 103 represented in FIG. 2. Furthermore, cap 200 is oriented in relation to substrate 100 in such a way that first and second stops 201, 202 point in the direction of seismic mass 500 and hollow space 204 is open in the direction of seismic mass 500. Via frame 203, cap 200 is fixedly connected to substrate 100, in particular via a firm bond, for example by gluing, vitrification, anodic bonding, etc., seismic mass 500 being situated perpendicular to main extension plane 101 between substrate 100 and cap 200. In a first coverage region 401, first stop 201 perpendicular to main extension plane 101 covers a first area 501 of seismic mass 500, while in a second coverage region 402, second stop 202 covers a second area 502 of seismic mass 500, first area 501 being situated on first seismic partial mass 1 and second area 502 being situated on second seismic partial mass 2. The size of first coverage region 401 parallel to main extension plane 101 is essentially identical to the size of second coverage region 402, so that a first electrostatic interaction between first area 501 and first stop 201 is essentially equal in magnitude to a second electrostatic interaction between second area 502 and second stop 202. The first and second electrostatic interactions thus mutually offset one another with respect to the deflection characteristics of seismic mass 500 about pivot axis 102, so that no or only immaterial influencing of the deflection characteristics by first and/or second stop 201, 202 is present. In particular, a resulting torque on the seismic mass is avoided due to the offsetting of the first and second electrostatic interactions. The first and second electrostatic interactions are indicated schematically by the arrows. In addition, first and second areas 501, 502 are preferably at an equal distance from pivot axis 102. Perpendicular to main extension plane 101, first stop 201 is at a distance from first area 501 in such a way that a first deflection of seismic mass 500 about pivot axis 102 is limited by contact between first stop 201 and first area 501, while perpendicular to main extension plane 102, second stop 202 is preferably at an equal distance from second area 502, so that a second deflection of seismic mass 500 about pivot axis 102 which is opposite to the first deflection is limited by contact between second stop 202 and second area 502. This prevents damage to the sensor caused by excessively large first and second deflections of seismic mass 500.

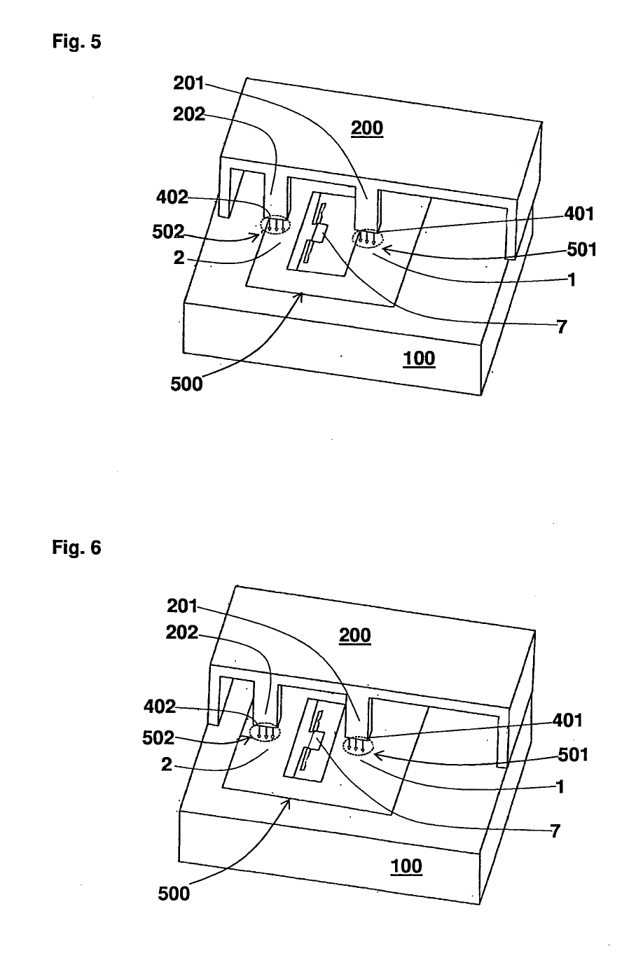

Schematic perspective views of sensors according to a second and third specific embodiment of the present invention are represented in FIGS. 4 and 5, the second and third specific embodiments being essentially identical to the first specific embodiment illustrated in FIG. 3, a difference being that cap 200 is slightly displaced in relation to substrate 100 in a direction parallel to main extension plane 101. At least in the second specific embodiment, first area 501 therefore includes a first edge area of first seismic partial mass 1 and second area 502 includes a second edge area of second seismic partial mass 2. Since first and second stops 201, 202 are designed as part of cap 200, the distance between first and second stops 201 and 202 is constant, so that the size of first and second coverage regions 401, 402 caused by the displacement of cap 200 in relation to substrate 100 is changed by the same amount. The sizes of first and second coverage regions 401, 402 are thus independent of a displacement of cap 200 in relation to substrate 100 and are connected to the same electrical potential, so that the first and second electrostatic interactions are essentially mutually offset independent of a displacement of cap 200 in relation to substrate 100, and no or only comparatively little resulting torque acts on seismic mass 500. In a particularly advantageous manner, the manufacturing tolerances for the positioning of cap 200 on substrate 100 are substantially increased.

A schematic perspective view of a sensor according to a fourth specific embodiment of the present invention is represented in FIG. 6, the fourth specific embodiment being essentially identical to the third specific embodiment represented in FIG. 5, open space 10 being smaller and first seismic partial mass 1 being larger. First and second areas 501, 502 thus no longer include a first and a second edge area, although the first and second electrostatic interactions essentially offset one another nonetheless.

1-8. (canceled)

9. A sensor comprising: a substrate, a cap and a seismic mass, the substrate having a main extension plane, the seismic mass being deflectable perpendicular to the main extension plane, a first stop of the cap covering a first area of the seismic mass perpendicular to the main extension plane in a first coverage region and a second stop of the cap covering a second area of the seismic mass perpendicular to the main extension plane in a second coverage region, wherein the first and second coverage regions parallel to the main extension plane are of essentially equal size.

10. The sensor as recited in claim 9, wherein the seismic mass is situated perpendicularly to the main extension plane essentially between the substrate and the cap.

11. The sensor as recited in claim 9, wherein the seismic mass is designed as a rocker structure, one pivot axis of the rocker structure being situated parallel to the main extension plane essentially between the first and second areas.

12. The sensor as recited in claim 9, wherein the seismic mass includes a first seismic partial mass and a second seismic partial mass, the first seismic partial mass having the first area and the second seismic partial mass having the second area.

13. The sensor as recited in claim 12, wherein the first and second seismic partial masses are joined to one another by webs.

14. The sensor as recited in claim 10, wherein the seismic mass includes a first seismic partial mass and a second seismic partial mass, the first seismic partial mass having the first area and the second seismic partial mass having the second area.

15. The sensor as recited in claim 11, wherein the seismic mass includes a first seismic partial mass and a second seismic partial mass, the first seismic partial mass having the first area and the second seismic partial mass having the second area.

16. The sensor as recited in claim 9, wherein the first area includes a first edge area of the first seismic partial mass and the second area includes a second edge area of the second seismic partial mass.

17. The sensor as recited in claim 10, wherein the first area includes a first edge area of the first seismic partial mass and the second area includes a second edge area of the second seismic partial mass.

18. The sensor as recited in claim 11, wherein the first area includes a first edge area of the first seismic partial mass and the second area includes a second edge area of the second seismic partial mass.

19. The sensor as recited in claim 9, wherein the first and second stops are situated in relation to the seismic mass in such a way that a first electrostatic interaction is provided between the first stop and the first area and is essentially identical to a second electrostatic interaction between the second stop and the second area.

20. The sensor as recited in claim 10, wherein the first and second stops are situated in relation to the seismic mass in such a way that a first electrostatic interaction is provided between the first stop and the first area and is essentially identical to a second electrostatic interaction between the second stop and the second area.

21. The sensor as recited in claim 11, wherein the first and second stops are situated in relation to the seismic mass in such a way that a first electrostatic interaction is provided between the first stop and the first area and is essentially identical to a second electrostatic interaction between the second stop and the second area.

22. The sensor as recited in claim 9, wherein the sensor includes a micromechanical sensor.

23. The sensor as recited in claim 22, wherein the micromechanical sensor is a micromechanical acceleration sensor which is provided to be sensitive to acceleration forces perpendicular to the main extension plane.

24. A method for manufacturing a sensor as recited in claim 9, comprising placing the cap together with the first and second stops on the substrate in one assembly step in such a way that the first and second coverage regions are essentially of equal size.
